(19) United States
(12) Patent Application Publication
(10) Pub. No.: US 2025/0081364 A1
(43) Pub. Date: Mar. 6, 2025

(54) DISPLAY MODULE AND DISPLAY DEVICE

(71) Applicant: KUNSHAN GO-VISIONOX OPTO-ELECTRONICS CO., LTD., Kunshan (CN)

(72) Inventor: Chang LIN, Kunshan (CN)

(73) Assignee: KUNSHAN GO-VISIONOX OPTO-ELECTRONICS CO., LTD., Kunshan (CN)

(21) Appl. No.: 18/950,181

(22) Filed: Nov. 18, 2024

Related U.S. Application Data
(63) Continuation of application No. PCT/CN2022/127066, filed on Oct. 24, 2022.

(30) Foreign Application Priority Data
Aug. 2, 2022 (CN) 202210923984.5

(51) Int. Cl. H05K 5/02

(52) U.S. Cl. CPC H05K 5/02

(57) ABSTRACT

The present application provides a display module and a display device, the display module includes a bending zone and a non-bending zone which are adjacently arranged; the display module includes a flexible screen and a support component which are laminated, and the support component is located on a backlight side of the flexible screen; the support component is provided with a first groove, and the first groove is located on a side of the bending zone close to the non-bending zone. The first groove may reduce the rigidity of the support component on the side of the bending zone close to the non-bending zone and alleviate the crease in the support component, preventing the crease of this part of the support component from being too sharp and thus alleviating the crease of the display module.

### CROSS-REFERENCE TO RELATED APPLICATIONS

This application is a continuation of International Application No. PCT/CN2022/127066, filed on Oct. 24, 2022, which claims priority to Chinese Patent Application No. 202210923984.5, entitled with “DISPLAY MODULE AND DISPLAY DEVICE”, and filed with the China National Intellectual Property Administration on Aug. 2, 2022. The disclosures of the aforementioned applications are hereby incorporated by reference in their entireties.

### TECHNICAL FIELD

The present application relates to the field of display technology, and in particular, to a display module and a display device.

### BACKGROUND

Flexible display panels have special product forms such as folding, large-angle bending, and curling, etc., and thus have increasing applications.

For example, a foldable display panel may achieve a large display area when the display panel is in a flattened state; when the display panel is in a folded state, it may have a small storage volume and is easy to carry, thereby gaining widespread attention. In the related art, a display module may include a display panel and a support component, and the support component is located on a backlight surface of the display panel to form support for the display panel.

However, the above-mentioned display panel has a relatively severe crease.

### SUMMARY

In view of at least one of the above technical problems, embodiments of the present application provide a display module and a display device, in which the crease of the display module may be alleviated, thereby improving a display effect of the display module and the display device.

In order to achieve the above objects, embodiments of the present application provide the following technical solutions.

A first aspect of embodiments of the present application provide a display module, including a bending zone and a non-bending zone which are adjacently arranged along a first direction, and includes a flexible screen and a support component laminated on the flexible screen, located on a backlight side of the flexible screen and provided with a first groove located on a side of the bending zone close to the non-bending zone.

The display module provided by the embodiments of the present application may include a bending zone and a non-bending zone which are adjacently arranged; the display module includes a flexible screen and a support component laminated on the flexible screen, and the support component is located on a backlight side of the flexible screen and is used to form a support for the flexible screen. The support component is provided with a first groove, and the first groove is located on a side of the bending zone close to the non-bending zone. The first groove may reduce the rigidity of the support component on the side of the bending zone close to the non-bending zone, so that this part of the support component is easy to bend and the stress of the part of the support component during bending is decreased, reducing the occurrence of plastic deformation in the part of the support component, thereby alleviating the crease in the support component. In addition, this can avoid the crease of the part of the support component from being too sharp, so that the crease of the part of the support component is relatively gentle. In this way, the crease of the display module may be alleviated and the influence on the display effect of the display module and the display device may be reduced, improving the visual experience of users.

A second aspect of embodiments of the present application provides a display device, including the display module in the first aspect.

The display device provided by the embodiments of the present application may include a display module, and the display module may include a bending zone and a non-bending zone which are adjacently arranged along a first direction; the display module includes a flexible screen and a support component which are laminated, and the support component is located on a backlight side of the flexible screen and is used to form a support for the flexible screen. The support component is provided with a first groove, and the first groove is located on a side of the bending zone close to the non-bending zone. The first groove may reduce a rigidity of the support component on the side of the bending zone close to the non-bending zone, so that this part of the support component is easy to bend and the stress of the part of the support component during bending is decreased, reducing the occurrence of plastic deformation in the part of the support component, thereby alleviating the crease in the support component. In addition, this may avoid the crease of the part of the support component from being too sharp, making the crease of the part of the support component relatively gentle. Thus, the crease of the display module may be alleviated and the influence on the display effect of the display module and the display device may be reduced, improving the visual experience of users.

The configuration of the present application as well as its other inventive objects and beneficial effects will be more obvious and easy to be understood through the description of the embodiments in conjunction with the drawings.

### BRIEF DESCRIPTION OF DRAWINGS

In order to illustrate the embodiments of the present application or the technical solutions in the prior art more clearly, the drawings required in the description of the embodiments or in the prior art will be briefly introduced below. Obviously, the drawings in the following description are only embodiments of the present application. For a person skilled in the art, other drawings may also be obtained based on these drawings without creative work.

FIG. 1 is a structural schematic diagram of a display module provided by an embodiment of the present application.

FIG. 2 is another structural schematic diagram of a display module provided by an embodiment of the present application.

FIG. 3 is still another structural schematic diagram of a display module provided by an embodiment of the present application.

FIG. 4 is a structural schematic diagram of a first groove provided by an embodiment of the present application.

FIG. 5 is another structural schematic diagram of a first groove provided by an embodiment of the present application.

FIG. 6 is still another structural schematic diagram of a first groove provided by an embodiment of the present application.

FIG. 7 is a structural schematic diagram of a second groove provided by an embodiment of the present application.

FIG. 8 is another structural schematic diagram of a second groove provided by an embodiment of the present application.

FIG. 9 is still another structural schematic diagram of a second groove provided by an embodiment of the present application.

FIG. 10 is a structural schematic diagram of a third groove provided by an embodiment of the present application.

FIG. 11 is another structural schematic diagram of a third groove provided by an embodiment of the present application.

FIG. 12 is still another structural schematic diagram of a third groove provided by an embodiment of the present application.

FIG. 13 is a structural schematic diagram of a second groove and a third groove provided by an embodiment of the present application.

FIG. 14 is a structural schematic diagram of a contour of a display module in Example 1 measured by a 3D contour measuring instrument.

FIG. 15 is a top view of the contour of the display module in Example 1 measured by a 3D contour measuring instrument.

FIG. 16 is a structural schematic diagram of a contour of a display module in Example 2 measured by a 3D contour measuring instrument.

FIG. 17 is a top view of the contour of the display module in Example 2 measured by a 3D contour measuring instrument.

FIG. 18 is a graph of a depth of crease of the display module of Example 1.

FIG. 19 is a graph of a depth of crease of the display module of Example 2.

### DESCRIPTION OF REFERENCE SIGNS

100: display module; 100a: bending zone; 101a: first bending zone;
102a: second bending zone; 100b: non-bending zone; 101b: first non-bending zone;
102b: second non-bending zone; 100c: edge zone; 100d: central zone;
110: support component; 111: first surface; 112: second surface;
121: first groove; 122: second groove; 123: third groove;
124: adhesive component; 130: flexible screen; 131: protective layer;
132: substrate; 133: luminescent layer; 134: touch layer;
135: filter layer; 136: cover plate; 137: connection layer.

### DESCRIPTION OF EMBODIMENTS

Through long-term research by the inventor, it has been found that in the related art, a display module may include a flexible screen and a support component, and the support component is located on a backlight side of the flexible screen and may form a support for the flexible screen. In addition, under action of an external force, the support component may drive the flexible screen to bend and flatten.

However, film layers in the display module which is located in a bending zone are deformed by an external force, and a recovery ability of deformation of materials of the film layers is limited. When the deformation does not exceed an elastic limit of the material, the deformation produced on the material is a reversible elastic deformation; after the external force is removed, the deformation is eliminated and the material may return to its original shape. When the deformation exceeds the elastic limit of the material, the deformation produced on the material is an irreversible plastic deformation; after the external force is removed, the deformation cannot be completely eliminated, and the material cannot fully return to its original shape. As a result, the display module located in the bending zone produce a crease, thereby affecting the display effect of the display module and the display device, and reducing the visual experience of users.

Based on at least one of the above technical problems, embodiments of the present application provide a display module and a display device, where the display module may include a bending zone and a non-bending zone which are arranged adjacent to each other in a first direction; the display module includes a flexible screen and a support component laminated on the flexible screen, and the support component is located on a backlight side of the flexible screen and is used to form a support for the flexible screen. The support component is provided with a first groove, and the first groove is located on a side of the bending zone close to the non-bending zone. The first groove may reduce the rigidity of the support component on the side of the bending zone close to the non-bending zone, so that this part of the support component is easy to bend, and the stress of the part of the support component during bending is decreased, reducing the occurrence of plastic deformation in the part of the support component, thereby alleviating the creases in the support component. In addition, this may avoid the crease of the part of the support component from being too sharp, making the crease of the part of the support component relatively gentle. In this way, the crease of the display module may be alleviated and the influence on the display effect of the display module and the display device may be reduced, improving the visual experience of users.

In order to make the purposes, technical solutions and advantages of the embodiments of the present application clearer, the technical solutions in the embodiments of the present application will be described clearly and completely below in conjunction with the drawings in the embodiments of the present application. Obviously, the described embodiments are some of the embodiments of the present application, but not all of the embodiments. Based on the embodiments in the present application, all the other embodiments obtained by the person skilled in the art without creative work fall within the protection scope of the present application.

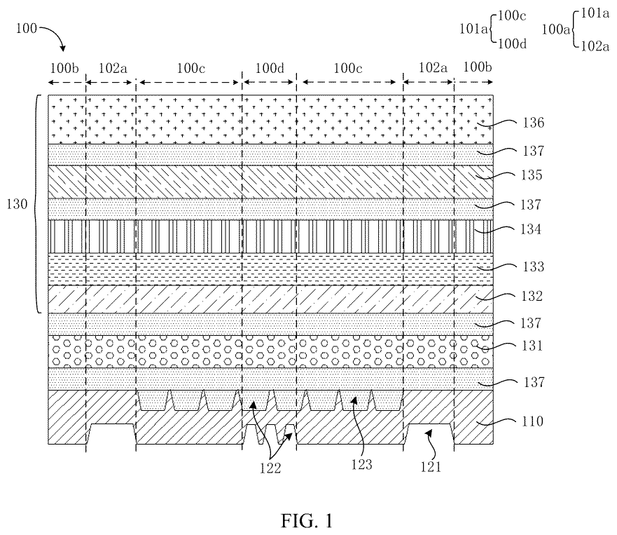

A display device provided by an embodiment of the present application will be described below in conjunction with FIGS. 1 to 19.

This embodiment provides a display device, and the display device may include a display module 100. The display device may be a mobile or fixed terminal with the display module 100, such as electronic paper, a mobile phone, a tablet computer, a television, a display, a notebook computer, a digital photo frame, a super personal computer, a navigator, etc.

A display module 100 provided by an embodiment of the present application is described below.

As shown in FIG. 1, a display module 100 may include a flexible screen 130, and the flexible screen 130 may be an organic light-emitting diode (OLED for short) display screen, a micro light emitting diode (Micro LED or μLED for short) display screen.

The flexible screen 130 may include a light-emitting side and a backlight side which are arranged opposite to each other, where the light-emitting side may be used for displaying a picture, and the backlight side is the side of the flexible screen 130 away from the light-emitting side. An upper side of the flexible screen 130 shown in FIG. 1 is the light-emitting side, and a lower side of the flexible screen 130 shown in FIG. 1 is the backlight side.

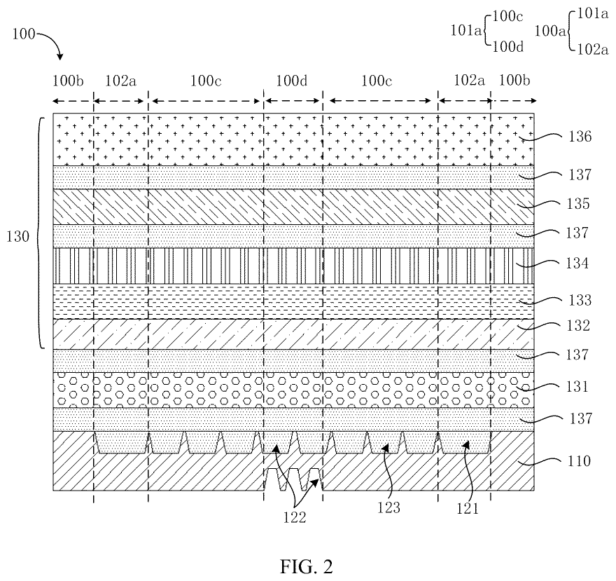

As shown in FIG. 2, a display module 100 may include a support component 110 which is located on the backlight side of the flexible screen 130, and the support component 110 is used to form a support for the flexible screen 130 to avoid the flexible screen 130 from collapsing due to pressing by the user during use and thus affecting the user experience.

The display module 100 may include a bending zone 100a and a non-bending zone 100b (the non-bending zone 100b is only partly shown in FIG. 2) which are adjacently arranged, that is, the bending zone 100a is arranged adjacent to the non-bending zone 100b. For example, the bending zone 100a and the non-bending zone 100b may be adjacently arranged along a first direction, and the first direction is an arrangement direction of the bending zone 100a and the non-bending zone 100b. The numbers of both the bending zone 100a and the non-bending zone 100b are at least one, and the bending zone 100a and the non-bending zone 100b are alternately arranged. For example, the number of the bending zone 100a may be 1, 2, 3 or any number greater than 3. The number of the non-bending zone 100b may be 1, 2, 3 or any number greater than 3.

An embodiment of the present application is described by an example where there is one bending zone 100a and two non-bending zone 100b, with the two non-bending zones 100b being connected by the bending zone 100a.

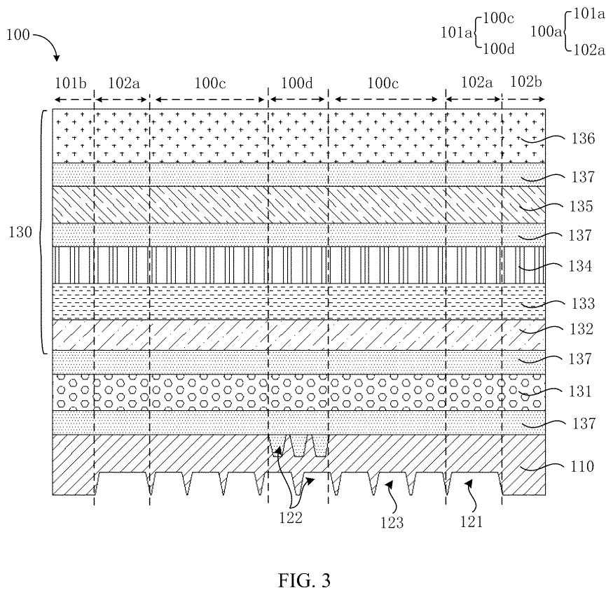

As shown in FIG. 2 and FIG. 3, the two non-bending zones 100b may include a first non-bending zone 101b and a second non-bending zone 102b, and the bending zone 100a is located between the first non-bending zone 101b and the second non-bending zone 102b. The display module 100 located in the bending zone 100a may be bent and flattened, so as to realize the folding and flattening of the display module 100.

It should be noted that the display module 100 may include a flattened state, a folded state, and an intermediate state between them, and the state of the display module 100 is also states of the flexible screen 130, the support component 110 and the display device. After the support component 110 is connected to the flexible screen 130, the user applies a force to the flexible screen 130 through the support component 110, and the support component 110 may drive the flexible screen 130 to switch between the flattened state and the folded state.

As shown in FIG. 3, the flattened state refers to a state in which each part of the display module 100 is substantially on the same plane. At this time, the first non-bending zone 101b, the second non-bending zone 102b and the bending zone 100a are substantially on the same plane, and an included angle between the first non-bending zone 101b and the second non-bending zone 102b is approximately 180 degrees. In the flattened state, the display module 100 has a larger display area to ensure better user experience.

The folded state refers to that the bending zone 100a of the display module 100 is bent, and that the display modules 100 of the first non-bending zone 101b and the second non-bending zone 102b at least partially overlap in a thickness direction of the display modules 100 and the included angle between the first non-bending zone 101b and the second non-bending zone 102b is approximately 0 degrees. In the folded state, the display module 100 and the display device having the display module 100 have a small volume, which facilitates the storage and carrying of the display device.

In some embodiments, the display device may be an inwardly folded display device, that is, when the display device is in a folded state, the folded flexible screen 130 is located on an inner side of the support component 110, and the support component 110 may protect the flexible screen 130. At this time, the flexible screens 130 of the first non-bending zone 101b and the second non-bending zone 102b are arranged facing each other.

In some embodiments, the display device may be an outwardly folded display device, that is, when the display device is in a folded state, the folded flexible screen 130 is located on an outer side of the support component 110, and the flexible screen 130 can realize a display function in the folded state to meet the needs of different display scenes. At this time, the flexible screens 130 of the first non-bending zone 101b and the second non-bending zone 102b are arranged back to back.

Continuing to refer to FIG. 3, the bending zone 100a may include a first bending zone 101a and a second bending zone 102a, and the second bending zone 102a is located between the first bending zone 101a and the non-bending zone 100b. The first bending zone 101a is provided between two second bending zones 102a, the first bending zone 101a and the first non-bending zone 101b are connected by one second bending zone 102a, and the first bending zone 101a and the second non-bending zone 102b are connected by another second bending zone 102a. For example, the display module 100 may be bent in a shape of a water drop, and a distance between flexible screens 130 of two non-bending zones 100b is relatively small, so that the entry of external dust between the two flexible screens 130 is reduced, thereby protecting the flexible screens 130.

Along an arrangement direction (i.e., the first direction) of the bending zone 100a and the non-bending zone 100b, the first bending zone 101a may include two edge zones 100c located on opposite sides and a central zone 100d located between the two edge zones 100c. Two second bending zones 102a are each connected to the central zone 100d by one edge zone 100c.

Each film layer of a flexible screen 130 provided by an embodiment of the present application is described below.

A protective layer 131 may be arranged between the support component 110 and the flexible screen 130, and the protective layer 131 may be used to isolate water, oxygen and the like in the environment to protect the flexible screen 130. Where a connection layer 137 may be provided between the protective layer 131 and the support component 110 and a connection layer 137 may be provided between the protective layer 131 and the flexible screen 130, so that the protective layer 131 is stably connected to the support component 110 and the flexible screen 130, respectively. For example, the connection layer 137 may be formed of an optically transparent adhesive, an optically transparent resin, a pressure-sensitive adhesive, or the like.

As shown in FIG. 3, a flexible screen 130 may include a substrate 132 and a luminescent layer 133 located on the substrate 132. The substrate 132 may provide support for the remaining structural layers to be subsequently arranged. The substrate 132 may be a rigid substrate 132 or a flexible substrate 132.

The luminescent layer 133 may include an anode layer, a pixel layer and a cathode layer, which are laminated in sequence, and the anode layer is located on a side of the cathode layer facing the array substrate. The anode layer may be a pixel electrode, and the cathode layer may be a common electrode. Where the pixel layer may include a plurality of pixels, and the pixels are light-emitting units of the flexible screen 130. The plurality of pixels may be arranged in an array, and the plurality of pixels may include, but are not limited to, a red pixel, a green pixel, and a blue pixel. In other examples, the plurality of pixels may also include a white pixel.

A pixel circuit is arranged between the luminescent layer 133 and the substrate 132, and the pixel circuit is electrically connected to the luminescent layer 133, and the pixel circuit is used for driving the luminescent layer 133 to emit light. The pixel circuit may include a thin film transistor (TFT for short) and a capacitor structure.

Continuing to refer to FIG. 3, the flexible screen 130 may include a touch layer 134. The touch layer 134 is located on a side of the luminescent layer 133 away from the substrate 132, and the touch layer 134 is used to realize a touch function.

The flexible screen 130 may include a filter layer 135. The filter layer 135 is located on a side of the touch layer 134 away from the substrate 132, and the filter layer 135 may be used to reduce the reflection of ambient light, thereby improving the display effect of the flexible screen 130. For example, the filter layer 135 may be a polarizer. Alternatively, the filter layer 135 may include a color resistance and a light-shielding layer, and the color resistance is located in a luminous zone, and the light-shielding layer is located in the non-luminous zone. The color resistance may be used to filter out a light, which is different in color from the color resistance itself, from the ambient light, the light-shielding layer may be formed of a material that may block light and absorb the light irradiated on the light-shielding layer, and the light-shielding layer may have a relatively dark color (e.g., black).

In the above, the flexible screen 130 may include a luminous zone and a non-luminous zone, and the luminous zone corresponds to the pixels, which are located in the luminous zone. For example, the luminous zone may be coincident with the pixels; in addition, a non-luminous zone may be arranged between adjacent luminous zones, and the non-luminous zone may be arranged around the periphery of the luminous zone.

In an embodiment where the filter layer 135 includes the color resistance and the light-shielding layer, the filter layer 135 may be directly prepared on a surface of a side of the touch layer 134 facing away from the substrate 132, thereby eliminating the need for an adhesive layer for bonding between the touch layer 134 and the filter layer 135, which may reduce glue extrusion, glue stacking and other phenomenon during the bending process, so as to alleviate the creases caused by glue extrusion and glue stacking. In the embodiment where the filter layer 135 is a polarizer, a connection layer 137 may be arranged between the polarizer and the touch layer 134.

The flexible screen 130 may include a cover plate 136. The cover plate 136 is located on a side of the filter layer 135 facing away from the substrate 132, and the cover plate 136 is used to protect the flexible screen 130 so as to prevent users from scratching the flexible screen 130 when using it. For example, a connection layer 137 may be arranged between the cover plate 136 and the filter layer 135, and the connection layer 137 is used to connect the cover plate 136 and the filter layer 135; in addition, the connection layer 137 may also be used to provide a flat surface.

In the above, any one of the material, thickness and other parameters of the connection layers 137 between the protective layer 131 and the support component 110, between the protective layer 131 and the flexible screen 130, between the filter layer 135 and the cover plate 136, and between the filter layer 135 and the touch layer 134 may be the same or different.

It should be noted that the second bending zone 102a may be a starting position of the bending zone 100a, and may also be a starting position of the crease of the display module 100 of the bending zone 100a. During the bending process, the display module 100 in the non-bending zone 100b is not bent and the display module 100 of the second bending zone 102a is the starting position of bending, which is likely to cause the display module 100 of the second bending zone 102a to be subjected to a great stress, resulting in a sharp crease of the display module 100 in the second bending zone 102a.

The support component 110 provided by an embodiment of the present application is described below.

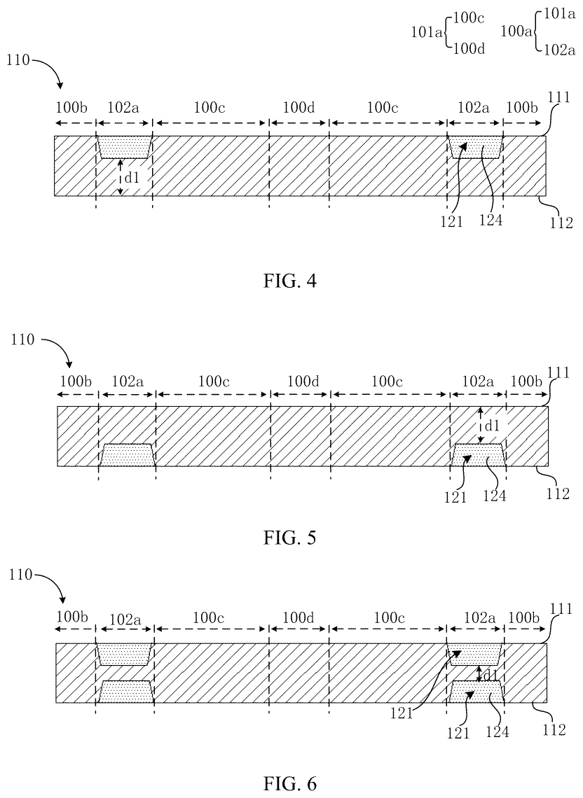

As shown in FIG. 4, the support component 110 may include a first surface 111 and a second surface 112, which are arranged opposite to each other along a thickness direction, where the first surface 111 is a surface of a side of the support component 110 close to the flexible screen 130, and the second surface 112 is a surface of a side of the support component 110 facing away from the flexible screen 130. For example, a material of the support component 110 may include stainless steel, titanium alloy, magnesium-aluminum alloy, etc.

Exemplarily, a thickness of the support component 110 may be in a range of 100 μm-200 μm, so that the support component 110 may be prevented from being too thin to ensure the supporting effect of the support component 110; and also may be prevented from being too thick, avoiding an influence of the support component 110 on a thickness of the display module 100. For example, the thickness of the support component 110 may range from 120 μm to 150 μm. The thickness of the support component 110 may be 100 μm, 120 μm, 150 μm, 180 μm, 200 μm, or any value from 100 μm to 200 μm.

As shown in FIG. 4, the support component 110 may be provided with a first groove 121, and the first groove 121 may be located on a side of the bending zone 100a close to the non-bending zone 100b. The thickness of the support component 110 at the first groove 121 is relatively thin and the rigidity of the support component 110 at the first groove 121 is reduced, so that the display module 100 corresponding to this part of the support component 110 is easy to bend and the stress of the part of the support component 110 is reduced during bending, reducing the occurrence of plastic deformation of the part of the support component 110 and alleviating the crease of the part of the support component 110. In addition, it may prevent the crease of the part of the support component 110 from being too sharp, making the crease of the part of the support component 110 relatively gentle. The crease of the display module 100 may be thus alleviated, reducing the influence on the display effect of the display module 100 and the display device, and improving the visual experience of users.

Specifically, the first groove 121 may be located in the second bending zone 102a, and the first groove 121 may reduce the rigidity of the support component 110 of the second bending zone 102a, so that the support component 110 of the second bending zone 102a is easy to bend and the stress of the support component 110 of the second bending zone 102a is reduced during bending, reducing the occurrence of plastic deformation of the support component 110 of the second bending zone 102a, thereby alleviating the crease of the support component 110 of the second bending zone 102a. In addition, it may prevent the crease of the support component 110 of the second bending zone 102a from being too sharp, making the crease of the support component 110 of the second bending zone 102a relatively gentle. In this way, the crease of the display module 100 may be alleviated, reducing the influence on the display effect of the display module 100 and the display device, and improving the visual experience of users.

Where, rigidity, which refers to the ability of a material or structure to resist elastic deformation when subjected to a force, is a characterization of the difficulty of elastic deformation of a material or structure. The greater the rigidity, the greater the stress that causes deformation. The less the rigidity, the less the stress that causes deformation, and the better the bending performance.

Continuing to refer to FIG. 4, an adhesive component 124 may be arranged in the first groove 121, and the adhesive component 124 may be used to connect the support component 110 with the structural components located on the support component 110. In addition, the adhesive component 124 may also fill the first groove 121 to avoid the influence of the first groove 121 on the flatness of the support component 110.

Exemplarily, the rigidity of the adhesive component 124 may be less than the rigidity of the support component 110. The rigidity of the adhesive component 124 is relatively small, which may prevent the crease of the display module 100 of the second bending zone 102a from being too sharp, so as to alleviate the crease of the display module 100 of the second bending zone 102a. In other examples, the adhesive component 124 may be formed of a flexible material, and the adhesive component 124 may provide a buffer against a stress of a film layer near it, thereby protecting the film layer near it and improving an impact resistance of the display module 100. For example, the adhesive component 124 may be formed of an optically transparent adhesive, an optically transparent resin, a pressure-sensitive adhesive, a foam adhesive, or the like.

At least one of the first surface 111 and the second surface 112 of the support component 110 may be provided with an opening of the first groove 121.

In some examples, as shown in FIG. 4, the opening of the first groove 121 is located on a surface of a side of the support component 110 facing the flexible screen 130, that is, the opening of the first groove 121 is located on the first surface 111. For example, a surface of the adhesive component 124 in the first groove 121 may be flush with the first surface 111, thereby providing a relatively flat surface for the flexible screen 130 and forming a good support. Where, there may be at least one first groove 121. When there is one first groove 121, the one first groove 121 may partially or completely cover the second bending zone 102a. When there are multiple first grooves 121, the multiple first grooves 121 may partially or completely cover the second bending zone 102a.

In another examples, as shown in FIG. 5, the opening of the first groove 121 is located on a surface of a side of the support component 110 facing away from the flexible screen 130, that is, the opening of the first groove 121 is located on the second surface 112. For example, the adhesive component 124 in the first groove 121 may be connected with a rotating shaft in the display device, thereby fixing the support component 110. The surface of the adhesive component 124 in the first groove 121 may be flush with the second surface 112, and the adhesive component 124 between the support component 110 and the rotating shaft being arranging in the first opening 121 with the opening located on the second surface 112 may avoid the influence of the adhesive component 124 on the flatness of the second surface 112, and may also avoid the adhesive component 124 from causing the support component 110 to protrude and thus affecting the flatness of the first surface 111 of the support component 110. Since a connection layer 137 is arranged between the support member 110 and the protective layer 131, if the opening of the first groove 121 is arranged on the first surface 111 and the adhesive component 124 is arranged in the first groove 121, one side of the first surface 111 of the support component 110 is provided with both the connection layer 137 and the adhesive component 124, which may lead to more adhesive material on the side on which the first surface 111 of the support component 110 is located, and thus glue extrusion, glue stacking and other phenomenon are easy to occur when the display module 100 is bending, resulting in deepened crease. Therefore, arranging the opening of the first groove 121 on the second surface 112 may avoid too much adhesive material on a side where the first surface 111 of the support component 110 is located, and thus glue extrusion, glue stacking and other phenomenon are not easy to occur in the display module 100, which is conducive to the improvement of the crease. There may be at least one first groove 121 with the opening located on the second surface 112, the principle of which is similar to that of the first groove 121 with the opening located on the first surface 111, and will not be repeated here.

In other examples, as shown in FIG. 6, both of the first surface 111 and the second surface 112 of the support component 110 may be provided with the opening of the first groove 121, the principle of which has already been explained and will not be repeated here. Any one of parameters, such as groove depth and opening size, of the first grooves 121 with openings located on different sides may be the same or different. Any one of parameters, such as groove depth and opening size, of the first grooves 121 with openings located on the same side may be the same or different.

Exemplarily, along an arrangement direction of the bending zone 100a and the non-bending zone 100b, a length of the opening of the first groove 121 may range from 0.5 mm to 3 mm, so that the length of the opening of the first groove 121 may be prevented from being too small, reducing the preparation difficulty; further the length of the opening of the first groove 121 may also be prevented from being too large, having little influence on the supporting effect of the supporting component 110. For example, the length of the opening of the first groove 121 may be 0.5 mm, 1 mm, 1.5 mm, 2 mm, 2.5 mm, 3 mm or any value from 0.5 mm to 3 mm.

Exemplarily, the groove depth of the first groove 121 may be less than or equal to 0.1 mm, thereby the groove depth of the first groove 121 may be prevented from being too small, reducing the preparation difficulty; further the groove depth of the first groove 121 may also be prevented from being too large, having little influence on the supporting effect of the supporting component 110. For example, the groove depth of the first groove 121 may range from 0.05 mm to 0.075 mm. The groove depth of the first groove 121 may be 0.05 mm, 0.06 mm, 0.07 mm, 0.08 mm, 0.09 mm, 0.1 mm or any value less than 0.1 mm.

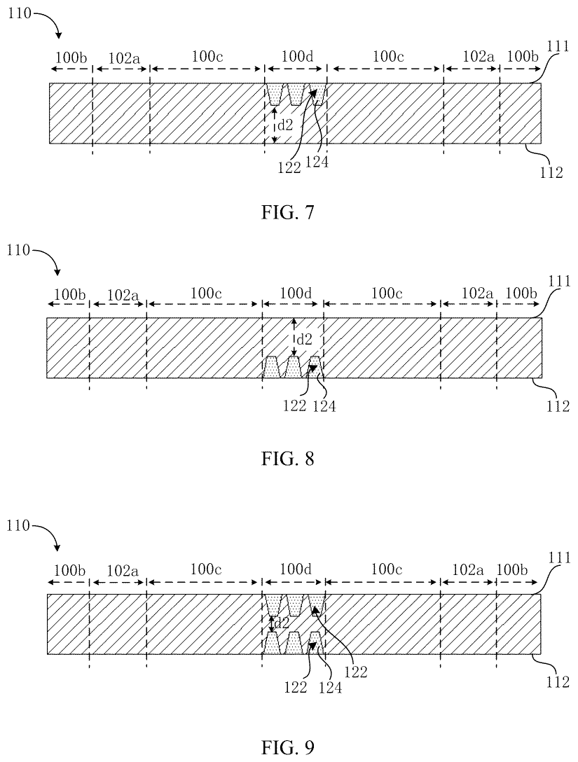

In some embodiments, as shown in FIG. 7, at least a second groove 122 may be provided on a part of the support component 110 located in the central zone 100d, and the at least a second groove 122 may reduce the rigidity of the support component 110 of the central zone 100d, so that it is easy for the support component 110 of the central zone 100d to bend and the stress of the support component 110 of the central zone 100d during bending is decreased, reducing the occurrence of plastic deformation in the support component 110 of the central zone 100d, which may alleviate the crease in the support component 110 of the central zone 100d. In this way, the crease of the display module 100 may be alleviated and the influence on the display effect of the display module 100 and the display device may be reduced, improving the visual experience of users.

In the above, an adhesive component 124 may be disposed in the at least a second groove 122, the principle of which is similar to that of the adhesive component 124 in the first groove 121, and will not be repeated here.

The opening of the at least a second groove 122 may be located on at least one of the first surface 111 and the second surface 112. For example, as shown in FIG. 7, the opening of the second groove 122 is located on the first surface 111. Alternatively, as shown in FIG. 8, the opening of the second groove 122 is located on the second surface 112. Alternatively, as shown in FIG. 9, openings of some second grooves 122 are located on the first surface 111, and openings of other second grooves 122 are located on the second surface 112. The principle is similar to that of the first groove 121 being arranged on the support component 110, and will not be repeated here.

Exemplarily, along the arrangement direction of the bending zone 100a and the non-bending zone 100b, a length of the central zone 100d may be in the range of 1 mm to 5 mm, so that an area covered by the at least a second groove 122 may be prevented from being too small, having good improvement effect on the crease in the central zone 100d; further the area covered by the at least a second groove 122 may also be prevented from being too large, having little influence on the supporting effect of the supporting component 110. For example, the length of the central zone 100d may be 1 mm, 2 mm, 3 mm, 4 mm, 5 mm, or any value from 1 mm to 5 mm.

Exemplarily, along the arrangement direction of the bending zone 100a and the non-bending zone 100b, the length of the opening of the at least a second groove 122 may range from 0.5 mm to 1 mm. In this way, the length of the opening of the at least a second groove 122 may be prevented from being too small, reducing the preparation difficulty; further the length of the opening of the at least a second groove 122 may also be prevented from being too large, having little influence on the supporting effect of the supporting component 110. For example, the length of the opening of the at least a second groove 122 may be 0.5 mm, 0.6 mm, 0.7 mm, 0.8 mm, 0.9 mm, 1 mm, or any value from 0.5 mm to 1 mm.

Exemplarily, the groove depth of the at least a second groove 122 may be less than or equal to 0.1 mm. For example, the groove depth of the at least a second groove 122 may range from 0.05 mm to 0.075 mm. The groove depth of the at least a second groove 122 may be 0.05 mm, 0.06 mm, 0.07 mm, 0.08 mm, 0.09 mm, 0.1 mm or any value less than 0.1 mm. The principle is similar to that of the groove depth of the first groove 121, and will not be repeated here.

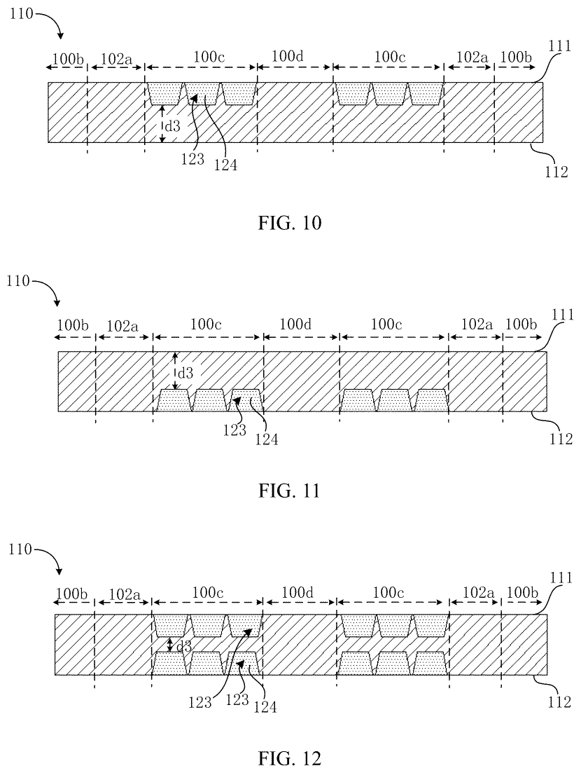

In some embodiments, as shown in FIG. 10, a third groove 123 may be provided on the part of the support component 110 located in the edge zone 100c, and the third groove 122 may reduce the rigidity of the support component 110 of the edge zone 100c, so that the support component 110 of the edge zone 100c is easy to bend and the stress of the support component 110 of the edge zone 100c during bending is decreased, reducing the occurrence of plastic deformation in the support component 110 of the edge zone 100c, which may alleviate the crease in the support component 110 of the edge zone 100c. In this way, the crease of the display module 100 may be alleviated, and the influence on the display effect of the display module 100 and the display device may be reduced, improving the visual experience of users.

In the above, an adhesive component 124 may be disposed in the third groove 123, the principle of which is similar to that of the adhesive component 124 in the first groove 121, and will not be repeated here.

Exemplarily, along the arrangement direction of the bending zone 100a and the non-bending zone 100b, the length of the opening of the third groove 123 may range from 0.5 mm to 1 mm. In this way, the length of the opening of the third groove 123 may be prevented from being too small, reducing the preparation difficulty; further the length of the opening of the third groove 123 may also be prevented from being too large, having little influence on the supporting effect of the support member 110. For example, the length of the opening of the third groove 123 may be 0.5 mm, 0.6 mm, 0.7 mm, 0.8 mm, 0.9 mm, 1 mm or any value from 0.5 mm to 1 mm.

Exemplarily, the groove depth of the third groove 123 may be less than or equal to 0.1 mm. For example, the groove depth of the third groove 123 may range from 0.05 mm to 0.075 mm. The groove depth of the third groove 123 may be 0.05 mm, 0.06 mm, 0.07 mm, 0.08 mm, 0.09 mm, 0.1 mm or any value less than 0.1 mm. The principle is similar to the groove depth of the first groove 121, and will not be repeated here.

The opening of a third groove 123 may be located on at least one of the first surface 111 and the second surface 112. For example, as shown in FIG. 10, the opening of the third groove 123 is located on the first surface 111. Alternatively, as shown in FIG. 11, the opening of the third groove 123 is located on the second surface 112. Alternatively, as shown in FIG. 12, openings of some third grooves 123 are located on the first surface 111, and openings of other third grooves 123 are located on the second surface 112. The principle is similar to that of the first groove 121 being arranged on the support component 110, and will not be repeated here.

It should be noted that the support component 110 may be provided with at least one of the grooves in the above embodiments, that is, the support component 110 may be provided with any one or more of the first groove 121, the second groove 122, and the third groove 123. When a plurality of grooves are arranged on the same side of the support component 110, two adjacent grooves may communicate with each other. For example, in an embodiment where the first surface 111 of the support component 110 is provided with the opening of the at least a second groove 122 and the opening of the third groove 123, adjacent second and third grooves 122, 123 may be communicated to form one groove.

The rigidity of the support component 110 of the bending zone 100a provided by an embodiment of the present application is described below.

It should be noted that, in the bending zone 100a, the closer to the center area 100d, the smaller the bending radius of the display module 100. The bending radius of the display module 100 of the central zone 100d is less than the bending radius of the display module 100 of the rest part of the bending zone 100a, resulting in that the bending stress (stress beared during bending) of the display module 100 of the central zone 100d is greater than the bending stress of the display module 100 of the rest part of the bending zone 100a, causing the display module 100 of the central zone 100d to be prone to sharp crease (for example, the crease in the bending zone 100a in a “V” shape).

In some embodiments, the rigidity of the part of the support component 110 located in the central zone 100d may be less than that of a part of the support component 110 located in the edge zone 100c, so that the bending stresses to which the support component 110 in the central zone 100d and the support component 110 in the edge zone 100c are subjected are relatively close to each other, and the plastic deformations of the support component 110 in the central zone 100d and the support component 110 in the edge zone 100c are relatively close to each other. In this way, the sharp crease in the display module 100 of the central zone 100d may be avoided, making the creases of the display modules 100 in the central zone 100d and the edge zone 100c relatively gentle as a whole.

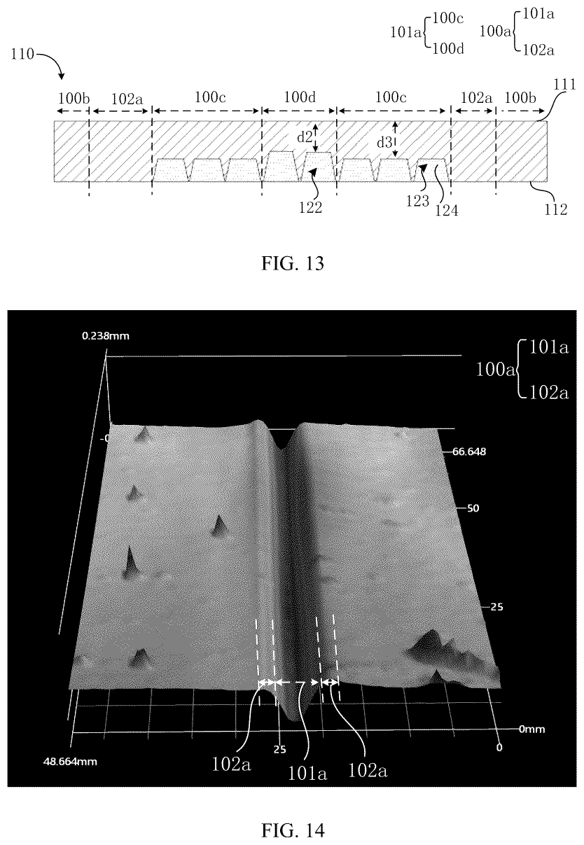

Specifically, a minimum thickness d2 (FIG. 13) of the part of the support component 110 located in the central zone 100d may be less than a minimum thickness d3 (FIG. 13) of the part of the support component 110 located in the edge zone 100c, so that the rigidity of the part of the support component 110 located in the central zone 100d is less than the rigidity of the part of the support component 110 located in the edge zone 100c.

Taking the central zone 100d provided with the at least a second groove 122 as an example, in the embodiment where the opening of the at least a second groove 122 is located on the first surface 111, as shown in FIG. 7, the minimum thickness d2 of the part of the support component 110 located in the central zone 100d may be a smallest distance between a groove bottom wall of the second groove 122 and the second surface 112. In the embodiment where the opening of the at least a second groove 122 is located on the second surface 112, as shown in FIG. 8, the minimum thickness d2 of the part of the support component 110 located in the central zone 100d may be a smallest distance between the groove bottom wall of the second groove 122 and the first surface 111. In the embodiment where both the first surface 111 and the second surface 112 are provided with the opening of the second grooves 122, as shown in FIG. 9, an orthographic projection of the second groove 122 with the opening located on the first surface 111 on the flexible screen 130 and an orthographic projection of the second groove 122 with the opening located on the second surface 112 on the flexible screen 130 are at least partially overlapped, and the minimum thickness d2 of the part of the support component 110 located in the central zone 100d may be a smallest distance between the groove bottom wall of the second groove 122 with the opening located on the first surface 111 and the groove bottom wall of the second groove 122 with the opening located on the second surface 112.

In addition, in an embodiment where the first groove 121 is arranged in the second bending zone 102a, a minimum thickness of a part of the support component 110 located in the second bending zone 102a is d1, the principle of which is similar to that of d2 and will not be repeated here. In an embodiment where the third groove 123 is arranged in the edge zone 100c, a minimum thickness of the part of the support member 110 located in the edge zone 100c is d3, the principle of which is similar to that of d2, and will not be repeated here.

It should be noted that the rigidity of the part of the support component 110 in the central zone 100d is affected by the groove depth of the second groove 122 and a distribution area of the second groove 122. Therefore, in addition to adjusting the rigidity of the part of the support component 110 in the central zone 100d through the groove depth, the rigidity of the part of the support component 110 in the central zone 100d may be adjusted by adjusting the distribution area of the second groove 122 in the central zone 100d. In another embodiments, a through-hole may also be arranged on the support component 110 in the central zone 100d, and the through-hole passes through the support component 110 along the thickness direction of the support component 110. By adjusting a distribution area of the through-hole in the central zone 100d, the rigidity of the part of the support component 110 of the central zone 100d may be adjusted. When the central zone 100d is provided with the through-hole, the second groove 122 may or may not be provided. The rigidity of the part of the support components 110 of the second bending zone 102a and the edge zone 100c is adjusted in a similar manner to the above, and will not be repeated here.

In some embodiments, the rigidity of the part of the support component 110 located in the second bending zone 102a may be greater than that of the part of the support component 110 in the edge zone 100c, so that the bending stresses to which the support component 110 in the edge zone 100c and the support component 110 in the second bending zone 102a are subjected are relatively close, making the creases of the display modules 100 of the edge zone 100c and the second bending zone 102a relatively gentle as a whole.

Specifically, the minimum thickness d3 of the part of the support component 110 located in the edge zone 100c may be smaller than the minimum thickness dl of the part of the support component 110 located in the second bending zone 102a, so that the rigidity of the part of the support component 110 located in the edge zone 100c is less than that of the part of the support component 110 located in the second bending zone 102a.

An embodiment of the present application where the at least a second groove 122 and the third groove 123 are simultaneously arranged is described below.

The first bending zone 101a may be provided with both at least a second groove 122 and the third groove 123. At this time, the overall rigidity of the support component 110 of the first bending zone 101a is reduced, thereby better realizing the bending performance of the support component 110 of the first bending zone 101a, so as to realize the folding of the display module 100.

Exemplarily, the at least a second groove 122 includes a plurality of second grooves 122, the first surface 111 and the second surface 112 of the support component 110 may be respectively provided with the opening of the second groove 122, and one of the first surface 111 and the second surface 112 of the support component 110 may be provided with the opening of the third groove 123. For example, as shown in FIG. 2, openings of some second grooves 122 may be located on the first surface 111, openings of other second grooves 122 may be located on the second surface 112, and the opening of the third groove 123 may be located on the first surface 111. The opening depths of the second and third grooves 122, 123 with the openings located on the first surface 111 may be the same, and thus the preparation processes of the second and third grooves 122, 123 with the openings located on the first surface 111 may be simplified. Since the second surface 112 is further provided with the opening of the at least a second groove 122, the minimum thickness d2 of the part of the support component 110 located in the central zone 100d is smaller than the minimum thickness d3 of the part of the support component 110 located in the edge zone 100c. Alternatively, as shown in FIG. 3, the openings of some second grooves 122 may be located on the first surface 111, the openings of other second grooves 122 may be located on the second surface 112, and the opening of the third groove 123 may be located on the second surface 112. The groove depths of the second and third grooves 122, 123 with the openings located on the second surface 112 may be the same, and thus the preparation processes of the second and third grooves 122, 123 with the openings located on the second surface 112 may be simplified. Since the first surface 111 is further provided with the opening of the at least a second groove 122, the minimum thickness d2 of the part of the support component 110 located in the central zone 100d is smaller than the minimum thickness d3 of the part of the support component 110 in the edge zone 100c.

Exemplarily, as shown in FIG. 13, the openings of both the at least a second groove 122 and the third groove 123 may be located on the second surface 112, and the groove depth of the second groove 122 is greater than the groove depth of the third groove 123, and thus the minimum thickness d2 of the part of the support component 110 located in the central zone 100d is smaller than the minimum thickness d3 of the part of the support component 110 located in the edge zone 100c. Or, the openings of both the at least a second groove 122 and the third groove 123 may be located on the first surface 111, and the groove depth of the second groove 122 is greater than the groove depth of the third groove 123, and thus the minimum thickness d2 of the part of the support component 110 located in the central zone 100d is smaller than the minimum thickness d3 of the part of the support component 110 located in the edge zone 100c.

In other examples, both the first surface 111 and the second surface 112 may be provided with the opening of the third groove 123, and one of the first surface 111 and the second surface 112 may be provided with the opening of the at least a second groove 122. Alternatively, both the first surface 111 and the second surface 112 may be provided with the opening of the at least a second groove 122 and the opening of the third groove 123. Alternatively, one of the first surface 111 and the second surface 112 may be provided with the opening of the at least a second groove 122, and the other of the first surface 111 and the second surface 112 may be provided with the opening of the third groove 123. The at least a second groove 122 and the third groove 123 include, but are not limited to, the above-mentioned arrangement mode, and have many other arrangement modes, and thus may be applied to a variety of scenarios.

It should be noted that, the support component 110 may further be provided with the first groove 121, the second groove 122 and the third groove 123 at the same time, and the opening of the first groove 121 may be arranged on at least one of the first surface 111 and the second surface 112. The arrangement of the second groove 122 and the third groove 123 has already been described and will not be repeated here.

Exemplarily, the openings of any one or more of the first groove 121, the second groove 122, and the third groove 123 have gradually increased size along the direction from the groove bottom walls to the openings. Taking the first groove 121 as an example, along a direction from the groove bottom wall to the opening of the first groove 121, an opening area of the first groove 121 gradually increases, that is, a cross-sectional area of the first groove 121 may gradually increase, and the size of the groove bottom of the first groove 121 is smaller than the size of the opening of the first groove 121. Where, the cross section may be a section parallel to a plane where the display module 100 is located. The groove bottom of the first groove 121 has a small size, ensuring the strength of the support component 110 and forming a good support for the flexible screen 130. The opening of the first groove 121 has a relatively large size, ensuring the bending of the support component 110. In addition, a groove side wall of the first groove 121 is an inclined surface, so that a contact area between the adhesive component 124 and the groove side wall is large, and the connection stability between the adhesive component 124 and the groove side wall is high.

Exemplarily, a distance between two adjacent grooves with the openings located on a same surface (the first surface 111 or the second surface 112) may be in the range of 0.2 mm to 0.5 mm, so that the distance may be prevented from being too close and the support component 110 has a good support effect; further the distance may also be prevented from being too far and the support component 110 has a good bending performance. For example, the distance may be any one or more of a distance between two adjacent first grooves 121, a distance between two adjacent second grooves 122, a distance between two adjacent third grooves 123, a distance between adjacent first and third grooves 121, 123, and a distance between adjacent second and third grooves 122, 123. The distance between two adjacent grooves with the openings located on a same surface may be 0.2 mm, 0.3 mm, 0.4 mm, 0.5 mm or any value from 0.2 mm to 0.5 mm.

The display modules 100 of Example 1 and Example 2 are compared below. For example, in Example 1, a support component 110 is not provided with a first groove 121, and only provided with a second groove 122 and a third groove 123, and the part of the support components 110 located in a central zone 100d and an edge zone 100c have the same rigidity. In Example 2, a support component 110 is provided with a first groove 121, a second groove 122 and a third groove 123, and the rigidity of the part of the support component 110 located in a central zone 100d is less than the rigidity of the part of the support component 110 located in an edge zone 100c.

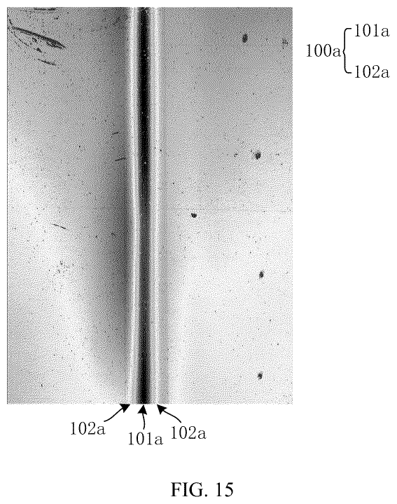

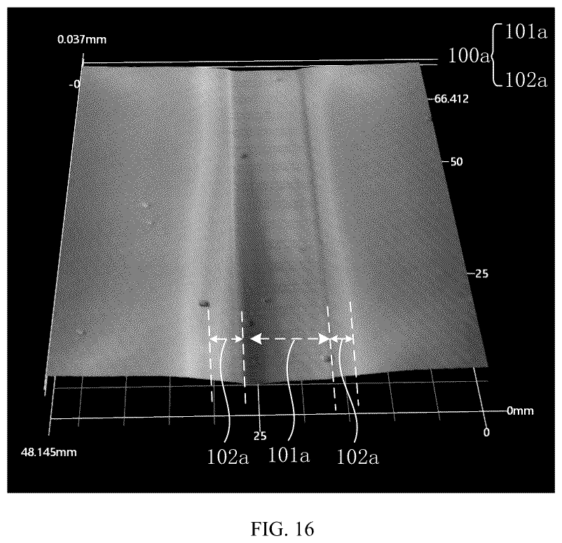

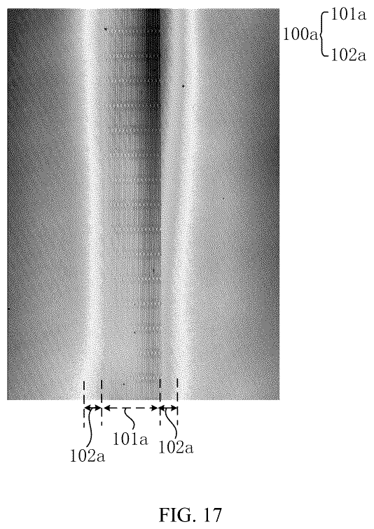

FIGS. 14 and 15 are contour views of a display module 100 of Example 1 before a crease is improved (Example 1), and FIGS. 16 and 17 are contour views of a display module 100 of Example 2 after the crease is improved (Example 2). By comparing the contour views of Examples 1 and 2, it can be seen that in Example 1, the crease of the display module 100 of a first bending zone 101a is a deep depression and in a shape of “V”; and the crease of a second bending zone 102a is a sharp protrusion. In Example 2, the crease of the display module 100 in a first bending zone 101a is a shallow and gentle depression; the crease of a second bending zone 102a is a concave slope and is relatively gentle. Therefore, by reasonably setting the rigidity of the support components 110 in the central zone 100d and the edge zone 100c and arranging the first groove 121 in the second bending zone 102a, the crease of the display module 100 becomes shallow and gentle, and thus the crease of the display module 100 is improved, and the display module 100 and the display device have good display effect.

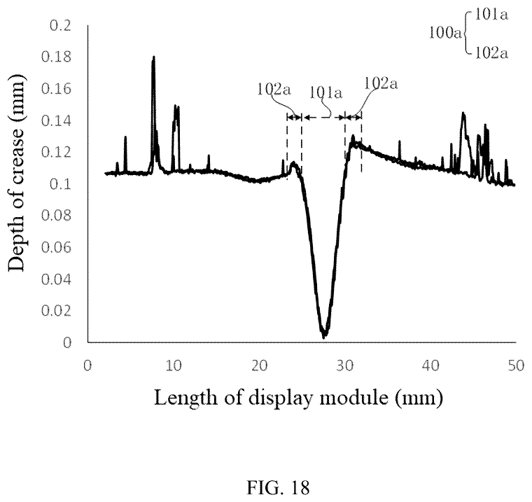

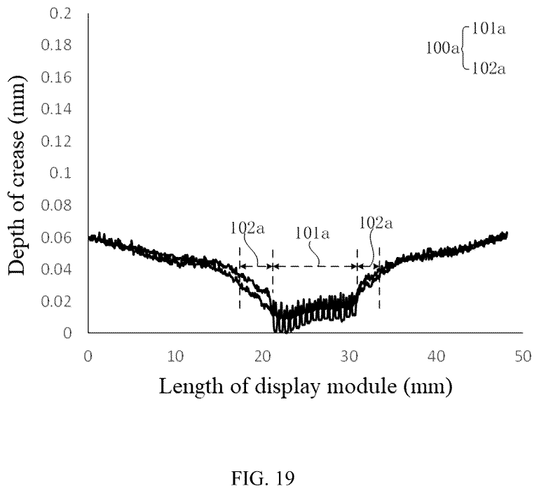

FIG. 18 (Example 1) and FIG. 19 (Example 2) are depth of crease curve graphs drawn according to a depth of crease corresponding to each position of a display module 100 in an arrangement direction of a bending zone 100a and a non-bending zone 100b. By comparing the a depth of crease curve graphs of Example 1 and Example 2, it can be seen that the crease of the display module 100 of the first bending zone 101a in Example 1 is a deep depression and in a shape of “V”, and the depth of the crease is about 0.11 mm; the crease of the second bending zone 102a is a sharp protrusion. The crease of the display module 100 of the first bending zone 101a in Example 2 is a shallow and gentle depression, and the depth of the crease is about 0.06 mm. The crease of the second bending zone 102a is a concave slope and is relatively gentle. By reasonably setting the rigidity of the support component 110 in the central zone 100d and the edge zone 100c and arranging the first groove 121 in the second bending zone 102a, the crease of the display module 100 becomes shallow and gentle, and thus the crease of the display module 100 is improved, and the display module 100 and the display device has a good display effect. Where, a length in FIGS. 18 and 19 refers to a length of the display module 100 in the arrangement direction of the bending zone 100a and the non-bending zone 100b.

It should be noted here that numerical values and numerical ranges involved in the embodiments of the present application are approximate values, and may be subject to a certain range of error due to the influence of the manufacturing process, and the error may be considered negligible by a person skilled in the art.

Finally, it should be noted that the above embodiments are only used to illustrate the technical solutions of the present application, but not to limit them; although the present application has been described in detail with reference to the foregoing embodiments, persons skilled in the art should understand that: they may still modify the technical solutions recorded in the foregoing embodiments, or equivalently replace some or all of the technical features therein; while these modifications or replacements do not make the essence of the corresponding technical solutions deviate from the scope of the technical solutions of the embodiments of the present application.

What is claimed is:

1. A display module, comprising a bending zone and a non-bending zone, the bending zone and the non-bending zone being adjacently arranged along a first direction; and comprising:
a flexible screen; and
a support component laminated on the flexible screen, located on a backlight side of the flexible screen and provided with a first groove located on a side of the bending zone close to the non-bending zone.

2. The display module according to claim 1, wherein the bending zone comprises:
a first bending zone; and
a second bending zone located between the first bending zone and the non-bending zone; the first groove is located in the second bending zone.

3. The display module according to claim 1, wherein an opening of the first groove is located on a surface of a side of the support component facing away from the flexible screen.

4. The display module according to claim 1, wherein an opening of the first groove is located on a surface of a side of the support component facing the flexible screen.

5. The display module according to claim 1, further comprising:
an adhesive component disposed in the first groove.

6. The display module according to claim 1, wherein, along the first direction, a length of an opening of the first groove ranges from 0.5 mm to 3 mm.

7. The display module according to claim 1, wherein a groove depth of the first groove is less than or equal to 0.1 mm.

8. The display module according to claim 2, wherein, along the first direction, the first bending zone comprises a central zone and two edge zones located respectively on two opposite sides of the central zone, and a rigidity of a part of the support component located in the edge zone is greater than a rigidity of a part of the support component located in the central zone.

9. The display module according to claim 8, wherein a rigidity of a part of the support component located in the second bending zone is greater than the rigidity of the part of the support component located in the edge zone.

10. The display module according to claim 8, wherein, along the first direction, a length of the central zone ranges from 1 mm to 5 mm.

11. The display module according to claim 8, wherein, along a thickness direction of the support component, the support component comprises a first surface and a second surface which are opposite to each other, and the part of the support component located in the central zone is provided with at least a second groove, and at least one of the first surface and the second surface of the support component is provided with an opening of the at least a second groove.

12. The display module according to claim 11, wherein, along the first direction, a length of the opening of the at least a second groove ranges from 0.5 mm to 1 mm.

13. The display module according to claim 11, wherein a groove depth of the at least a second groove is less than or equal to 0.1 mm.

14. The display module according to claim 11, wherein the part of the support component located in the edge zone is provided with a third groove, and the at least one of the first surface and the second surface of the support component is provided with an opening of the third groove;
a minimum thickness of the part of the support component located in the edge zone is greater than a minimum thickness of the part of the support component located in the central zone.

15. The display module according to claim 14, wherein the minimum thickness of the part of the support component located in the edge zone is less than a minimum thickness of a part of the support component located in the second bending zone.

16. The display module according to claim 14, wherein, along the first direction, a length of the opening of the third groove ranges from 0.5 mm to 1 mm; and
a groove depth of the third groove is less than or equal to 0.1 mm.

17. The display module according to claim 14, wherein the at least a second groove comprises a plurality of second grooves, the first surface and the second surface of the support component are respectively provided with the opening of the second groove, and the first surface or the second surface of the support component is provided with the opening of the third groove.

18. The display module according to claim 17, wherein the second groove and the third groove located on a same side of the support component along the thickness direction have a same groove depth.

19. The display module according to claim 14, wherein both the opening of the at least a second groove and the opening of the third groove are located on the first surface, or, both the opening of the at least a second groove and the opening of the third groove are located on the second surface, and a groove depth of the second groove is greater than a groove depth of the third groove.

20. A display device, comprising the display module according to claim 1.
